(19) United States
(12) Patent Application Publication
(10) Pub. No.: US 2006/0013352 A1
(43) Pub. Date: Jan. 19, 2006

(54) Shift register and flat panel display apparatus using the same

(76) Inventors: Ching-Wei Lin, Taoyuan City (TW); Chueh-Kuei Jan, Taipei City (TW)

Correspondence Address: MIN, HSIEH & HACK LLP, 8270 GREENSBORO DRIVE, SUITE 630, MCLEAN, VA, 22102, US

(21) Appl. No.: 10/980,781

(22) Filed: Nov. 4, 2004

Related U.S. Application Data
(60) Provisional application No. 60/587,660, filed on Jul. 13, 2004.

(51) Int. Cl. G11C 19/00

(52) U.S. Cl. 377/78

(57) ABSTRACT

A shift register is provided that is tolerant of variations or skew in its control clock signals. In even stages of the shift register, inverters are added respectively to the input terminal and the output terminal of a latch circuit. In addition, the shift register operates based on two control clock signals.

### CROSS-REFERENCE TO RELATED APPLICATION

This application claims the priority benefits of U.S. provisional application titled “SHIFT REGISTER” filed on Jul. 13, 2004, Ser. No. 60/587,660. All disclosure of this application is incorporated herein by reference.

### BACKGROUND OF THE INVENTION

1. Field of Invention

Embodiments of the present invention relate to a shift register.

2. Description of Related Art

Shift registers are a well known type of sequential logic circuit that are used mainly to temporarily store and transfer a data signal. A typical shift register comprises stages or groups of latch circuits or flip-flop circuits that are connected together in a chain so that the output of one stage becomes the input of the next stage. Each of the stages in a shift register are usually driven by one or more clock signals. Shift registers are widely used in various types of electronic devices, such as flat panel displays.

FIG. 3 shows a conventional shift register circuit 300. As shown, shift register 300 receives a start signal ST that is sequentially transferred through S stages of latch circuits Latch₁ to Latch_{S}. Shift register 300 is also configured to output signals OUT₁ to OUT_{S}. Shift register 300 operates based on a clock signal CLK and an inverted clock signal CLK (“XCLK”, hereafter), where XCLK is obtained by inverting the clock signal CLK. Complementary clock signals, such as CLK and XCLK, are used in conventional shift registers due to the operating characteristics of their components.

FIG. 4A shows a more detailed view of a conventional shift register 400. As shown, shift register 400 processes a data signal ST and operates based on clock signals CLK and XCLK. Shift register 400 comprises two stages of adjacent latch circuits 410 and 420. Latch circuit 410 includes one inverter 413 and two clocked inverters 411 and 415. Latch circuit 420 includes one inverter 423 and two clocked inverters 421 and 425. In latch circuits 410 and 420, inverters 413 and 415, as well as 423, and 425 are respectively connected together to form a flip-flop circuit.

The operation of shift register 400 will now be described. Signal ST is fed to clocked inverter 411 of latch circuit 410 and transferred to the next latch circuit 420 via the inverter 413. A set of output signals OUT_{K} and OUT_{K+1} can then obtained respectively from latch circuits 410 and 420 at the output of the inverters 413 or 423.

In order to control the progress of signal ST through shift register 400, latch circuits 410 and 420 sequentially latch signal ST in response to the rising and falling of one or more clock signals. In particular, latch circuits 410 and 420 are controlled by two clock signals CLK and XCLK. Clock signals CLK and XCLK are supplied to the control terminal of the clocked inverters 411, 415, 421, and 425 of latch circuits 410 and 420, respectively.

FIG. 4B shows an example of clock signals CLK and XCLK. As shown, clock signals CLK and XCLK are opposite in phase and have a 50% duty cycle. Complementary clock signals, such as CLK and XCLK are used in conventional shift registers due to the operating characteristics of their clocked inverters. The internal structure and operation of the clocked inverters of latch circuits 410 and 420, such as clocked inverters 411, 415, 421, and 425, will now be described with reference to FIG. 5.

FIG. 5 shows an example of a conventional clocked inverter, such as clocked inverters 411, 415, 421, and 425. In particular, a clocked inverter 500 is shown processing its input signal IN to produce an output signal OUT based on a set of complementary clock signals CKN and CKP. Typically, clocked inverter 500 is composed of two P-type MOS (“PMOS”) transistors M1 and M2 and two N-type MOS (“NMOS”) transistors M3 and M4.

Input signal IN is fed to PMOS transistor M1 and NMOS transistor M4. Meanwhile, clock signals CKP and CKN are fed to PMOS transistor M2 and NMOS transistor M3, respectively. Clock signals CKP and CKN have the same waveforms as CLK and XCLK, which were described with reference to FIG. 4B above. That is, CKP and CKN are also signals that have opposite phases and have a 50% duty cycle. As clock signals CKP and CKN transition from high to low and low to high, transistors M2 and M3 gate input signal IN to their output. An output signal OUT can then be obtained from between PMOS transistor M2 and NMOS transistor M3. Therefore, the operation of the clocked inverters in a conventional shift register circuit depends on a set of complementary clock signals.

Since, conventional shift registers use complementary clock signals that are opposite in phase and have a 50% duty cycle, they can be sensitive to variations or skew in the clocking signals. Clock signal variations can be caused by a variety of factors, such as gating delays, characteristics of a clock's wire, or temperature variations.

An example of a clocking skew or variation is shown with reference to FIG. 6. As shown, at time T1, clock signal CKP changes its phase from a logic high level to a logic low level. However, clock signal CKN does not change its phase from the logic low level to the logic high level for the time delay and but begin to change its phase after a delay time t. This delay of CKN relative to CKP, for example, may then cause transistor M2 to operate out of sync relative to transistor M3. This may then result in an erroneous output signal from clocked inverter 500 and/or shift register 400. Therefore, phase variations between clock signals can cause a conventional shift register to operate abnormally or even fail.

Therefore, it may be desirable to provide a shift register that is tolerant of variations in its clock signals.

### SUMMARY OF THE INVENTION

In accordance with embodiments of the invention, a shift register comprises a plurality of stages. Each stage comprises a corresponding latch circuit that includes a first clocked inverter and a latch loop. The first clocked inverter is controlled by a first clock signal and a second clock signal to invert an input signal and the inverted input signal is latched by the latch loop. The latched input signal is applied to a subsequent stage as the input signal. In even stages of the plurality of stages, a first inverter is disposed before the input terminal of the first clocked inverter for inverting the input signal for the corresponding latch circuit, and a second inverter is disposed after the output terminal of the latch loop for inverting the latched input signal as the output signal of the corresponding latch circuit in the even stage.

In accordance with other embodiments of the invention, a shift register for sequentially transferring a digital signal in synchronization with a first clock signal and a second clock signal is provided. The shift register comprises a plurality of sequentially connected stages in series. Each stage comprising a corresponding latch unit, each latch unit outputting a signal corresponding to an input signal based on the first clock signal and the second clock signal. The output signal is applied to a subsequent stage as the input signal for the latch unit of the subsequent stage. In even stages of the plurality of stages, a first inverter is disposed before the input terminal of the latch unit for inverting the input signal for the corresponding latch unit. A second inverter is disposed after the output terminal of the latch unit for inverting the output from the latch unit as the output signal of the corresponding latch circuit in the even stage.

In accordance with yet other embodiments of the invention, a shift register that processes an input signal based on a first clock signal and a second clock signal. The shift register comprises a first stage and a second stage. The first stage comprises a first latch circuit that latches the input signal based on the first and second clock signals. The second stage comprises a first inverter that inverts the output of the first stage, a second latch circuit coupled to the first inverter, and a second inverter that inverts an output of the second latch circuit.

Additional advantages of the invention will be set forth in the description which follows, and in part will be obvious from the description, or may be learned by practice of the invention. It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic block diagram of an exemplary display. (“Poly-Si TFT LCD”, hereinafter).

FIG. 2A is a schematic block diagram of a polycrystalline silicon thin-film-transistor liquid crystal display (Poly-Si TFT LCD).

FIG. 2B shows an exemplary data driving circuit.

FIG. 2C shows an exemplary gate driving circuit.

FIG. 3 is a schematic block diagram of a shift register.

FIG. 4A shows an example of two adjacent latch circuits in the shift register of FIG. 3.

FIG. 4B shows exemplary clock signals that are applied to the latch circuits of FIG. 4A.

FIG. 5 shows an example of a conventional clocked inverter which is implemented in the latch circuit shown in FIG. 4.

FIG. 6 shows clock signals that are applied to the latch circuits of FIG. 4A.

FIG. 7 shows adjacent latch circuits of a shift register that is consistent with embodiments of the present invention.

FIGS. 8 and 9 show exemplary clock signals that can be applied to the latch circuits of the shift register shown in FIG. 7.

FIG. 10 shows an exemplary shift register, which can be implemented in a data driving circuit or a gate driving circuit in a display.

### DESCRIPTION OF EMBODIMENTS

Various embodiments of the invention provide a shift register that is tolerant of variations or skew in its clocking signals. Shift registers that are consistent with the principles of the present invention can used in a driver circuit for a display, such as a flat panel display. In some embodiments, the shift register comprises multiple stages of latch circuits. Inverters may then be added to the input and output of the even numbered stages. In addition, the shift register may operate based on two different clock signals. The clock signals may have duty cycles other than 50% and may arbitrarily overlap each other.

Reference will now be made in detail to exemplary embodiments of the invention, which are illustrated in the accompanying drawings. Wherever possible, the same reference numbers will be used through the drawings to refer to the same or like parts.

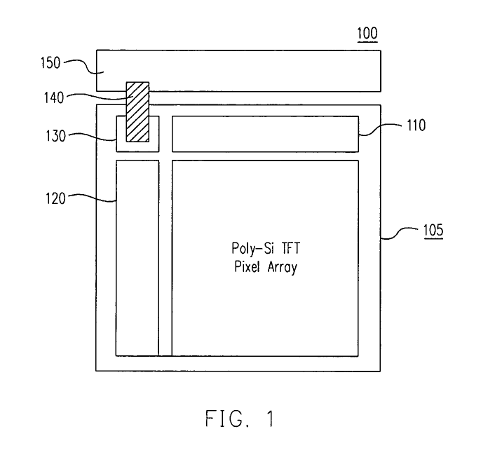

FIG. 1 illustrates one example of a display 100. Display 100 may be any type of display, such as a flat panel display. One skilled in the art will recognize that other types of displays, such as cathode ray tube (“CRT”) displays, liquid crystal displays (“LCD”), and other types of plasma displays, are consistent with the principles of the present invention. For example, display 100 may be implemented as an organic light emission display (OLED), field emission display (FED), plasma display panel (PDP), etc.

For purposes of explanation, display 100 is described as being implemented a polycrystalline silicon thin-film-transistor liquid crystal display (“Poly-Si TFT flat panel display”). In particular, display 100 can include a data driving circuit 110 and a gate driving circuit 120 that are formed on a glass substrate 105. A terminal part 130 is connected with an integrated printed circuit board (PCB) 150 using a film cable 140.

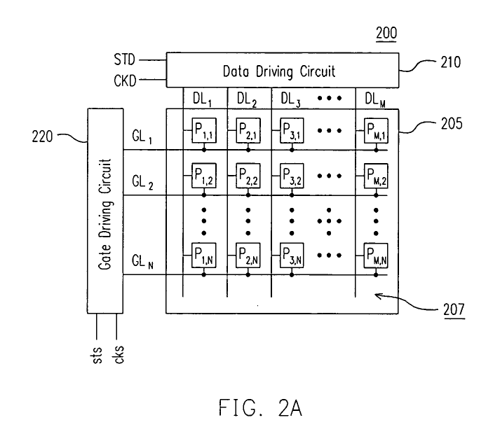

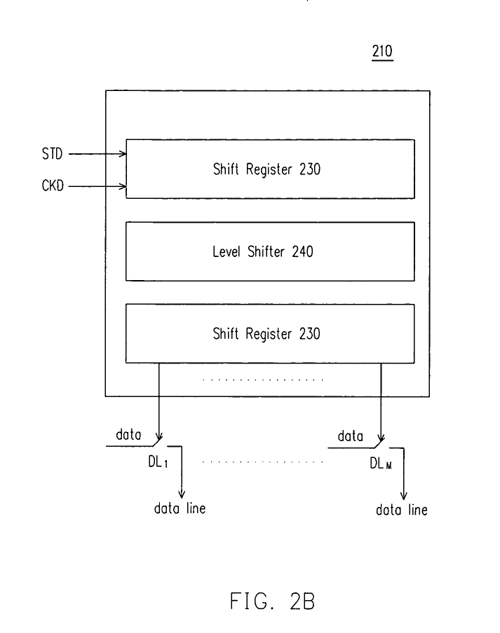

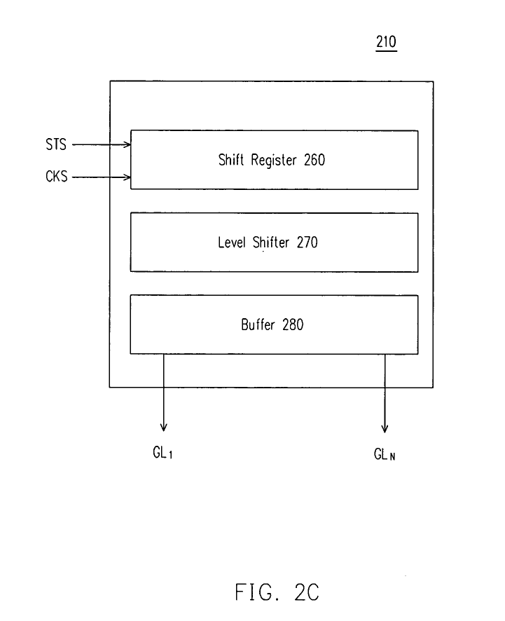

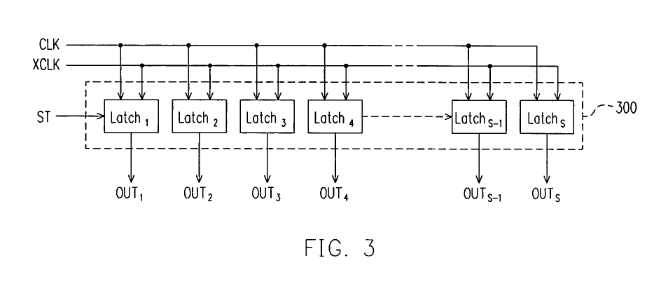

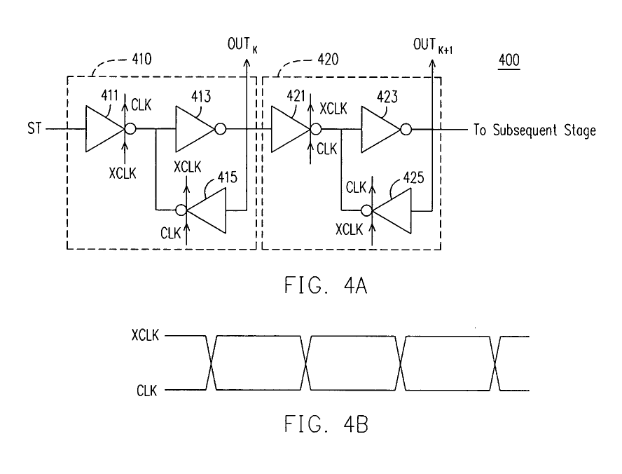

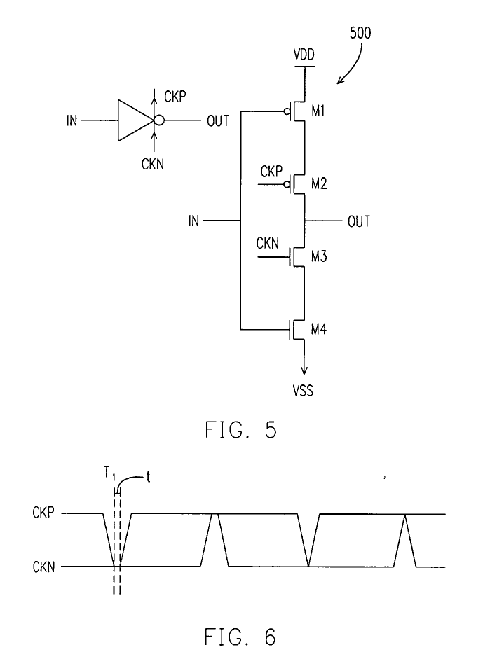

FIG. 2A shows a more detailed view of a Poly-Si TFT flat panel display 200. In particular, FIG. 2A schematically shows a structure of the Poly-Si TFT flat panel display apparatus 200. Display apparatus 200 can include a glass substrate 205 having a pixel array 207, a data driving circuit 210, and a gate driving circuit 220.

As shown in FIG. 2A, data driving circuit 210 can be coupled to pixel array 207 with M data signal lines DL₁ to DL_{M}. Gate driving circuit 220 can also be coupled to pixel array 207 via N scanning signal lines GL₁ to GL_{N}. Within pixel array 207, a pixel PIX_{i,j} is formed at the crossing of each data signal line DLᵢ (where “i” is an integer between 1 and M) and each scanning signal line GLⱼ (where “j” is an integer between 1 and N). Data driving circuit 210 and gate driving circuit 220 may be coupled to pixel array based on a variety of matrix architectures, such as single matrix or dual matrix.

In some embodiments, data driving circuit 210 and gate driving circuit 220 may address the pixels PIX_{i,j} based on active matrix addressing. However, other types of addressing may be supported by other embodiments of the present invention. For example, displays consistent with the principles of the present invention may also use passive matrix addressing.

In some embodiments, driving circuits 210 and 220 are integrated into display 200 using components made from thin film transistors. Of course one skilled in the art will recognize that driving circuits 210 and 220 may be implemented using any known component of hardware, software, firmware, or combination thereof. The structures of data driving circuit 210 and gate driving circuit 220 will now be described with reference to FIGS. 2B and 2C respectively.

FIG. 2B shows the basic structure of data driving circuit 210. As shown, data driving circuit 210 can include a shift register 230, a level shifter 240, and a buffer 250. These components will now be further described.

Shift register 230 receives a start signal STD and transfers it for display based on clocking signals CKD. Shift register 230 may operated based on well known methods, such as the point sequential driving method or line sequential driving method. Shift register 230 may be implemented and configured using known components. For example, in some embodiments, shift register 230 is implemented as a static shift register.

Level shifter 240 modulates the signals from shift register 230 into a level that can turn on a switching element. Level shifter 240 can be implemented using well known components.

Buffer 250 is optional and can control the timing of display data into pixel array 207, i.e., to lines DL₁ to DL_{M}. Buffer 250 can also be implemented using well known components.

FIG. 2C shows the basic structure of gate driving circuit 220. As shown, gate driving circuit can include a shift register 260, a level shifter 270, and a buffer 280.

Shift register 260 receives start signal STS and transfers it for display based on clocking signals CKS. Shift register 260 may be implemented and configured using known components. For example, in some embodiments, shift register 260 is also implemented as a static shift register.

Level shifter 270 modulates the signals from shift register 260 into a different level. Level shifter 270 can be implemented using well known components.

Buffer 280 can control the timing of driving signals to pixel array 207, i.e., lines GL₁ to GL_{N}. Buffer 250 can also be implemented using well known components.

Of course one skilled in the art will recognize that various other components may be included in data driving circuit 210 and gate driving circuit 220. For example, driving circuits 210 and 220 may also include components, such as an analog to digital converter and memory.

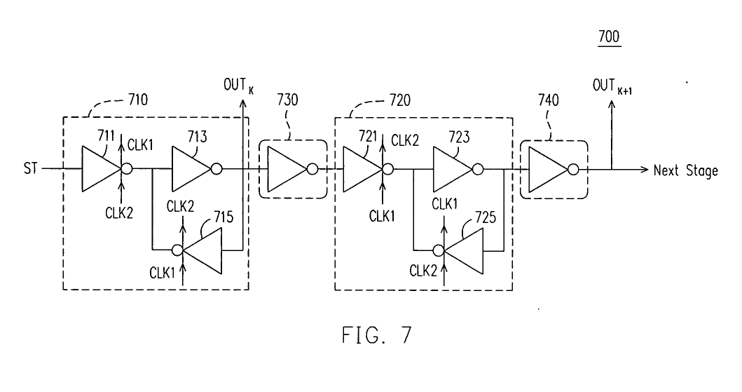

FIG. 7 shows an example of a shift register 700 that is consistent with embodiments of the present invention. In some embodiments, shift register 700 may be implemented in data driving circuit 210 and gate driving circuit 220 noted above. In addition, in some embodiments, various stages of shift register 700 may be bounded inverters to aid in tolerating clocking variations and clock skew. For example, these inverters may serve as buffers or delay elements that essentially damp erroneous glitches that result from clocking variations. In addition, these inverters may serve to isolate errors caused by clocking variation or skew to just one stage. One example of the use of these bounding inverters will now be described.

In some embodiments, the odd stages (i.e., stages 1, 3, 5, etc.) of shift register 700 may comprise a latch circuit. that operates based on two clock signals. However, inverters may be added between the odd stages and the even stages (i.e., stages 2, 4, 6, etc.) of shift register 700. For example, as shown in FIG. 7, an inverter 730 is added between the output terminal of latch circuit 710 and the input terminal of latch circuit 720. A second inverter 740 is added between the output latch circuit 720 and the next stage of shift register 700. This architecture can be useful to set the phase of each input signal of each of the latch circuits to be the same with each other.

In addition, as noted above, shift register 700 may operate based on two clock signals. In various embodiments, the duty cycles of these two control clock signals may be configured to something other than 50%. Furthermore, the two clock signals may overlap at their logic low level (0-0 overlap) or logic high level (1-1 overlap) by an arbitrary amount.

As shown, shift register 700 may comprise adjacent latch circuits 710 and 720. A first inverter 730 can be disposed between the latch circuits 710 and 720. In addition, a second inverter 740 can be disposed between latch circuit 720 and the next stage of shift register 700 (not shown).

Latch circuit 710 may include an inverter 713 and two clocked inverters 711 and 715. As shown in FIG. 7, inverter 713 and clocked inverter 715 are connected together form a flip-flop circuit. During operation, a start signal ST is input into clocked inverter 711 and transferred via inverter 713 to the next stage of shift register 700. A first clock signal CLK1 and a second clock signal CLK2 are supplied to the control terminal of clocked inverters 711 and 715. Hence, latch circuit 710 latches the start signal ST received from a preceding latch circuit (not shown) and transfers the latched signal to the subsequent latch circuit (i.e., latch circuit 720) in response to the rising and falling of two clock signals CLK1 and CLK2. An output OUT_{K} from latch circuit 710 may also be obtained from the output of inverter 713.

Latch circuit 720 may include one inverter 723 and two clocked inverters 721 and 725. Inverter 723 and the clocked inverter 725 are connected to form a flip-flop circuit. During operation, the output of latch circuit 710 is taken as the input of latch circuit 720. In some embodiments, the output of latch circuit 710 is first inverted by the first inverter 730 and then is input into the clocked inverter 721 of latch circuit 720. Similar to latch circuit 710, latch circuit 720 may operate based on the rising and falling of two clock signals CLK1 and CLK2. The output of clocked inverter 721 is then latched and is transferred to the next stage via inverter 723. The output of inverter 723 may then be inverted by inverter 740. An output signal OUT_{K+1}, may then be obtained from the output of inverter 740.

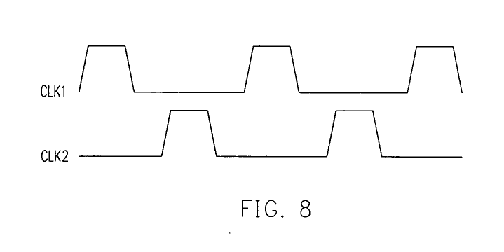

FIG. 8 shows exemplary waveforms for clock signals CLK1 and CLK2 that may be used in embodiments of the present invention. In the embodiment shown, the duty cycle of the first clock signal CLK1 is less than 50% and the duty cycle of the second clock signal CLK2 is also less than 50%. Duty cycles of less than 50% may be used by various embodiments of the present invention in order to ensure a certain interval or spread between the edges of these signals. Of course one skilled in the art will recognize that other duty cycles may be used by different embodiments of the present invention. In other embodiments, the first clock signal CLK1 and the second clock signal CLK2 can arbitrarily overlap each other.

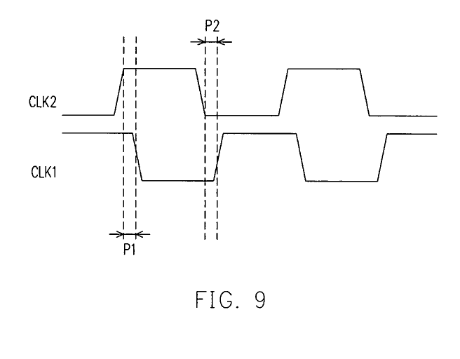

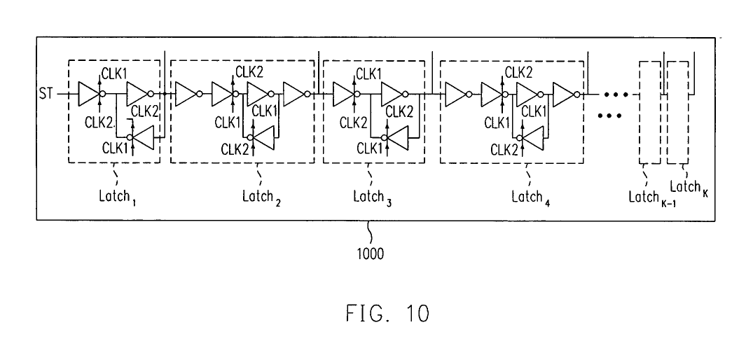

FIG. 9 shows exemplary waveforms for clock signals CLK1 and CLK2 in which they overlap. As shown, during the time period P1, the first clock signal CLK1 and the second clock signal CLK2 overlap at a logic high level (1-1 overlap). During the time period P2, the first clock signal CLK1 and the second clock signal CLK2 overlap at a logic low level (0-0 overlap).

FIG. 10 shows an embodiment of a K-stage shift register 1000 that is consistent with embodiments of the present invention. As noted, shift register 1000 can be implemented in a data driving circuit or a gate driving circuit in a flat panel display apparatus. As shown, shift register 1000 comprises a chain of K latch circuits. However, in each of the even stages (i.e., stages 2, 4, etc.), the latch circuit includes two additional inverters. As explained above, these additional inverters may be used to buffer or isolate errors due to clocking variation or skew.

During operation, a start signal ST is sequentially transferred through the latch circuits Latch₁ to Latch_{K} (K stages for example) based on a first clock signal CLK1 and a second clock signal CLK2. In some embodiments, the duty cycles of these two control clock signals CLK1 and CLK2 are configured to something other than 50%. Hence, the edges of clock signals CLK1 and CLK2 may have a desired interval or spread between each other. In some embodiments, this characteristic may be used to allow the components of shift register 1000, such as PMOS or NMOS transistors, to properly operate. However, in other embodiments of shift register 1000, the first clock signal CLK1 and the second clock signal CLK2 arbitrarily overlap each other.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A shift register comprising:
a plurality of stages, wherein each stage comprises a corresponding latch circuit that includes a first clocked inverter and a latch loop, the first clocked inverter is controlled by a first clock signal and a second clock signal to invert an input signal and the inverted input signal is latched by the latch loop, and the latched input signal is applied to a subsequent stage as the input signal; and
wherein in each even stage of the plurality of stages, a first inverter is disposed before the input terminal of the first clocked inverter for inverting the input signal for the corresponding latch circuit, and a second inverter is disposed after the output terminal of the latch loop for inverting the latched input signal as the output signal of the corresponding latch circuit in the even stage.

2. The shift register as claimed in claim 1, wherein the latch loop of each latch circuit comprise a third inverter and a second clocked inverter, an input terminal of the third inverter being connected to the output of the first clocked inverter and the output terminal of the second clocked inverter, an input terminal of the second clocked inverter being connected to the output of the third inverter, and
wherein the second clocked inverter is controlled by the first clock signal and the second clock signal.

3. The shift register as claimed in claim 1, wherein the duty cycles of the first clock signal and the second clock signal are not equal to 50%.

4. The shift register as claimed in claim 1, wherein the first clock signal and the second clock signal overlap each other.

5. A flat panel display using a shift register according to claim 1, comprising:
a flat panel including a plurality of pixels arranged in columns and rows, a plurality of data signal lines disposed for the columns of the pixels, and a plurality of scanning signal lines disposed for the rows of the pixels, image data for image display being supplied from the data signal lines to the pixels in synchronization with a scanning signal supplied from the scanning signal lines;
a data driving circuit for sequentially outputting the image data to the plurality of data signal lines in synchronization with a prescribed timing signal; and
a gate driving circuit for sequentially outputting the scanning signal to the plurality of scanning signal lines in synchronization with a prescribed timing signal,
wherein the data driving circuit includes the shift register as a circuit for sequentially shifting a sampling signal for receiving the image data in correspondence with the data signal lines.

6. The flat panel display apparatus of claim 5, wherein at least one of the data driving circuit and the gate driving circuit includes elements formed on a substrate constituting the flat panel as circuit elements constituting the driver, together with elements constituting the pixels.

7. The flat panel display apparatus of claim 5, wherein the flat panel is an active-matrix liquid crystal panel.

8. The flat panel display apparatus of claim 5, wherein the flat panel is an active-matrix organic light emission display (OLED) panel.

9. A flat panel display apparatus using a shift register according to claim 1, comprising:
a flat panel including a plurality of pixels arranged in columns and rows, a plurality of data signal lines disposed for the columns of the pixels, and a plurality of scanning signal lines disposed for the rows of the pixels, image data for image display being supplied from the data signal lines to the pixels in synchronization with a scanning signal supplied from the scanning signal lines;
a data driving circuit for sequentially outputting the image data to the plurality of data signal lines in synchronization with a prescribed timing signal; and
a gate driving circuit for sequentially outputting the scanning signal to the plurality of scanning signal lines in synchronization with a prescribed timing signal,
wherein the scanning signal line driver includes the shift register as a circuit for sequentially shifting the scanning signal in correspondence with the scanning signal lines.

10. The flat panel display apparatus of claim 9, wherein at least one of the data driving circuit and the gate driving circuit includes elements formed on a substrate constituting the flat panel as circuit elements constituting the driver, together with elements constituting the pixels.

11. The flat panel display apparatus of claim 9, wherein the flat panel is an active-matrix liquid crystal panel.

12. The flat panel display apparatus of claim 9, wherein the flat panel is an active-matrix organic light emission display (OLED) panel.

13. A shift register for sequentially transferring a digital signal in synchronization with a first clock signal and a second clock signal, the shift register comprising:
a plurality of stages connected in series, each stage comprising a corresponding latch unit, each latch unit outputting a signal corresponding to an input signal based on the first clock signal and the second clock signal, the output signal being applied to a subsequent stage as the input signal for the latch unit of the subsequent stage,
wherein in each even stage of the plurality of stages, a first inverter is disposed before the input terminal of the latch unit for inverting the input signal for the corresponding latch unit, and a second inverter is disposed after the output terminal of the latch unit for inverting the output from the latch unit as the output signal of the corresponding latch circuit in the even stage.

14. The shift register as claimed in claim 13, wherein the duty cycles of the first clock signal and the second clock signal are not equal to 50%.

15. The shift register as claimed in claim 13 wherein the first clock signal and the second clock signal overlap each other.

16. The flat panel display apparatus using a shift register according to claim 13 comprising:
a flat panel including a plurality of pixels arranged in columns and rows, a plurality of data signal lines disposed for the columns of the pixels, and a plurality of scanning signal lines disposed for the rows of the pixels, image data for image display being supplied from the data signal lines to the pixels in synchronization with a scanning signal supplied from the scanning signal lines;
a data driving circuit for sequentially outputting the image data to the plurality of data signal lines in synchronization with a prescribed timing signal; and
a gate driving circuit for sequentially outputting the scanning signal to the plurality of scanning signal lines in synchronization with a prescribed timing signal,
wherein the data driving circuit includes the shift register as a circuit for sequentially shifting a sampling signal for receiving the image data in correspondence with the data signal lines.

17. The flat panel display apparatus of claim 16, wherein at least one of the data driving circuit and the gate driving circuit includes elements formed on a substrate constituting the flat panel as circuit elements constituting the driver, together with elements constituting the pixels.

18. The flat panel display apparatus of claim 16, wherein the flat panel is an active-matrix liquid crystal panel.

19. The flat panel display apparatus of claim 16, wherein the flat panel is an active-matrix organic light emission display (OLED) panel.

20. An flat panel display apparatus using a shift register according to claim 13, comprising:
a flat panel including a plurality of pixels arranged in columns and rows, a plurality of data signal lines disposed for the columns of the pixels, and a plurality of scanning signal lines disposed for the rows of the pixels, image data for image display being supplied from the data signal lines to the pixels in synchronization with a scanning signal supplied from the scanning signal lines;
a data driving circuit for sequentially outputting the image data to the plurality of data signal lines in synchronization with a prescribed timing signal; and
a gate driving circuit for sequentially outputting the scanning signal to the plurality of scanning signal lines in synchronization with a prescribed timing signal,
wherein the scanning signal line driver includes the shift register as a circuit for sequentially shifting the scanning signal in correspondence with the scanning signal lines.

21. The flat panel display apparatus of claim 20, wherein at least one of the data driving circuit and the gate driving circuit includes elements formed on a substrate constituting the flat panel as circuit elements constituting the driver, together with elements constituting the pixels.

22. The flat panel display apparatus of claim 20, wherein the flat panel is an active-matrix liquid crystal panel.

23. The flat panel display apparatus of claim 20, wherein the flat panel is an active-matrix organic light emission display (OLED) panel.

24. A shift register that processes an input signal based on a first clock signal and a second clock signal, said shift register comprising:
a first stage comprising a first latch circuit that latches the input signal based on the first and second clock signals;
a second stage comprising a first inverter that inverts the output of the first stage, a second latch circuit coupled to the first inverter, and a second inverter that inverts an output of the second latch circuit.

25. The shift register of claim 24, wherein the first clock signal has a duty cycle that is less than 50%.

26. The shift register of claim 24, wherein the second clock signal has a duty cycle that is less than 50%.

27. The shift register of claim 24, wherein pulses of the first and second clock signals overlap each other.

28. The shift register of claim 24, further comprising:
at least one additional stage, coupled to the second stage, that comprises a third latch circuit that latches the output of the second stage based on the first and second clock signals.

29. The shift register of claim 24, wherein the first and second latch circuits each comprise:
a first clocked inverter that operates based on the first and second clock signals; and
a flip-flop circuit configured to pass the output of the first clocked inverter based on the first and second clock signals.

30. The shift register of claim 29, wherein the flip-flop circuit comprises:
a third inverter that is coupled to the output of the first clocked inverter; and
a second clocked inverter that is connected from the output to the input of the third inverter and operates based on the first and second clock signals.
